(19) United States
(12) Patent Application Publication
(10) Pub. No.: US 2012/0262422 A1
(43) Pub. Date: Oct. 18, 2012

(54) OPTICAL TOUCH MODULE AND METHOD THEREOF

(76) Inventor: Ching-Huan Liao, New Taipei City (TW)

(21) Appl. No.: 13/441,941

(22) Filed: Apr. 9, 2012

(30) Foreign Application Priority Data
Apr. 14, 2011 (TW) 100112945

(51) Int. Cl. G06F 3/042; H05K 13/00

(52) U.S. Cl. 345/175; 29/622

(57) ABSTRACT

An optical touch module includes a transparent cover plate, a light bar device, and an optical sensing device. The transparent cover plate has a touch surface. The light bar device is disposed along a side of the transparent cover plate, including a light emitting unit and a light guide bar. The light guide bar is disposed at a light emitting side of the light emitting unit for guiding light emitted by the light emitting unit into the transparent cover plate. The optical sensing device is disposed at a corner side of the transparent cover plate for sensing a reduced optical signal caused by total internal reflection of the light in the transparent cover plate being frustrated at a position where a touch object touches the touch surface. Accordingly, the optical sensing device can position the touch object based on the reduced optical signal.

### BACKGROUND OF THE INVENTION

1. Field of the Invention

The present invention relates to an optical touch module and a related method, and more specifically, to an optical touch module and a related method for positioning a touch object by frustrating total internal reflection of light in a transparent cover plate.

2. Description of the Prior Art

In general, a conventional design for optical touch positioning is to utilize a light interruption method to detect a position of a touch object on a touch surface. In this design, two optical sensing devices (e.g. a CMOS (Complementary Metal-Oxide Semiconductor) sensor) are respectively disposed at the left and right corners of a touch surface of a display panel, the overall height of which are higher than the touch surface of the display panel by about 3˜5 mm, infrared light emitting units are disposed near the optical sensing devices respectively, and a light reflection bar is disposed at the left, right, and bottom sides of the display panel respectively. In such a manner, light emitted by the infrared light emitting units can be distributed uniformly over the touch surface, and be incident into the light reflection bars at different angles. Subsequently, each light reflection bar can reflect the light back to the optical sensing devices along the original incident path of the light, so as to establish an optical sensing mechanism on the touch surface. Thus, when a user wants to utilize a touch object (e.g. the user's finger or a stylus) to touch the touch surface at a certain position for performing touch operations, the optical signal intensity sensed by the optical sensing device at this position is reduced greatly since the light is interrupted by the touch object at this position. Accordingly, the relative angles between the touch object and the optical sensing devices at the left and right corners of the touch surface can be determined, and then the plane coordinates of the touch object on the touch surface can be calculated based on the said relative angles and trigonometric functions so as to complete plane positioning of the touch object.

However, as mentioned above, since this design needs to additionally heighten the outer frame of the display panel for containing the optical sensing devices and the infrared light emitting units and the light reflection bars deform after being used over a period of time, this design can not only cause the problem that the appearance of the display panel is influenced and dust accumulate on the light reflection bars and the optical sensing devices easily, but also need to calibrate the position of the light reflection bar relative to the optical sensing device frequently. Furthermore, since the infrared light emitting unit (i.e. a spot light source) has different light intensity at different emitting angles and the probability that light is reflected back along its original incident path decreases greatly (only about 20%˜30%) when the light is incident into the light reflection bar at a large angle, the condition that signal attenuation of the light is too small when the touch object touches the touch surface at some specific position may occur in this design, so as to influence positioning accuracy of the optical sensing device.

### SUMMARY OF THE INVENTION

The present invention provides an optical touch module including a transparent cover plate, at least one light bar device, and at least one optical sensing device. The transparent cover plate is disposed on a display panel and has a touch surface. The light bar device is disposed along a side of the transparent cover plate. The light bar device includes at least one light emitting unit and a light guide bar. The light emitting unit is used for emitting light. The light guide bar is disposed at a light emitting side of the light emitting unit for guiding light emitted by the light emitting unit into the transparent cover plate. The optical sensing device is disposed at a corner side of the transparent cover plate for sensing a reduced optical signal caused by total internal reflection of the light in the transparent cover plate being frustrated at a position where a touch object touches the touch surface, and is used for positioning the touch object based on the reduced optical signal.

The present invention further provides a method for positioning a touch object on a plane. The method includes disposing a transparent cover plate on the plane, disposing at least one light emitting unit along at least one side of the transparent cover plate and a light guide bar located at a light emitting side of the light emitting unit, disposing an optical sensing device on at least one corner side of the transparent cover plate, the light guide bar guiding light emitted by the light emitting unit into the transparent cover plate, the optical sensing device sensing a reduced optical signal caused by total internal reflection of the light in the transparent cover plate being frustrated at a position where a touch object touches the touch surface, and the optical sensing device positioning the touch object based on the reduced optical signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a front view of an optical touch module according to an embodiment of the present invention.

FIG. 2 is a side view of the configuration of the optical touch module in FIG. 1.

FIG. 3 is a flowchart of a method for utilizing the optical touch module in FIG. 1 to position a touch object.

FIG. 4 is a side view of light in a transparent cover plate travelling in FIG. 1 in a total internal manner.

FIG. 5 is a side view of a touch surface of the transparent cover plate in FIG. 4 being touched by a touch object.

FIG. 6 is a partial side view of a transparent cover plate and a light guide bar according to another embodiment of the present invention.

FIG. 7 is a partial side view of a transparent cover plate and the light guide bar according to another embodiment of the present invention.

### DETAILED DESCRIPTION

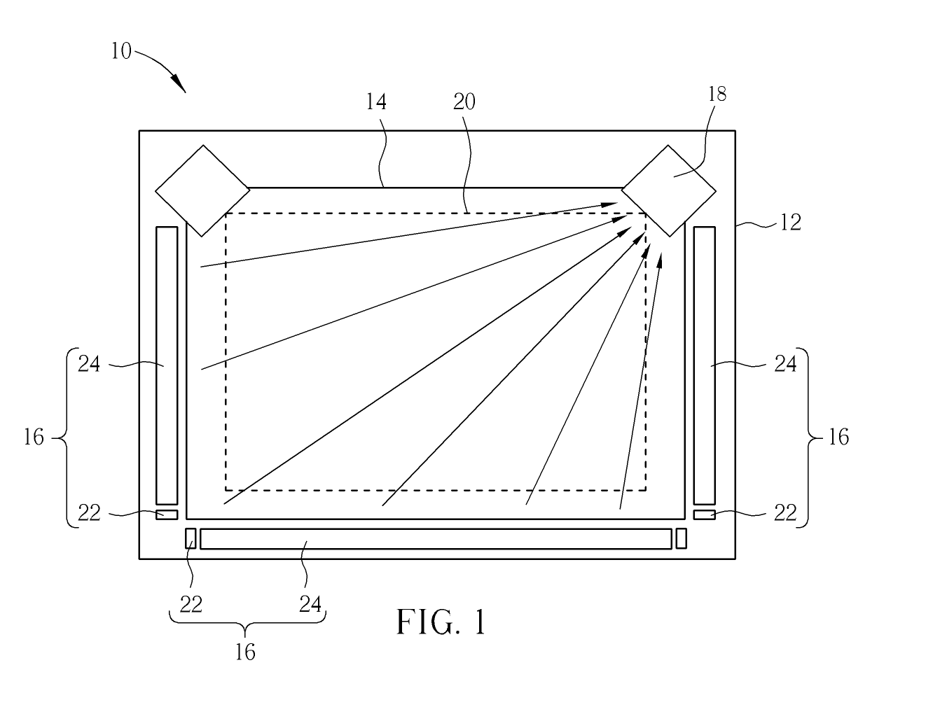

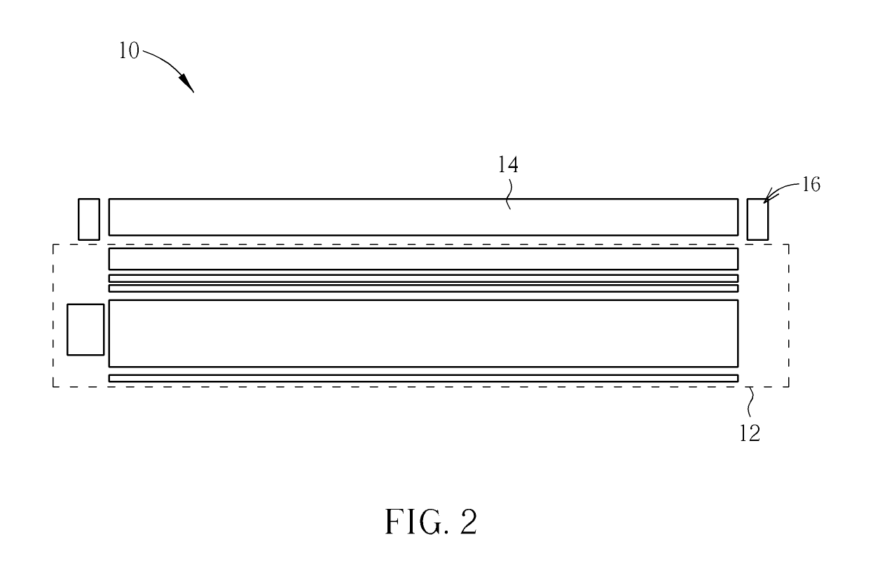

Please refer to FIG. 1 and FIG. 2. FIG. 1 is a front view of an optical touch module 10 according to an embodiment of the present invention. FIG. 2 is a side view of the configuration of the optical touch module 10 in FIG. 1. As shown in FIG. 1 and FIG. 2, the optical touch module 10 includes a transparent cover plate 14, at least one light bar device 16 (three shown in FIG. 1), and at least one optical sensing device 18 (two shown in FIG. 1). In the present invention, the optical touch module 10 is disposed on a plane, on which touch operations can be performed. In this embodiment, the plane is a display panel 12, but is not limited thereto. The display panel 12 includes components in a conventional display panel, such as a liquid crystal panel, a lens film, a diffusing film, a light guide plate, and a backlight source, and related description is omitted herein since it is commonly seen in the prior art. The transparent cover plate 14 is disposed on the display panel 12 and has a touch surface 20. The transparent cover plate 14 can be made of transparent material (e.g. glass or resin), the refractive index of which is between 1.5 and 1.6.

The light bar device 16 is disposed along a side of the transparent cover plate 14, meaning that the light bar device 16 and the transparent cover plate 14 are substantially located at the same horizontal surface. As shown in FIG. 1, in this embodiment, the light bar device 16 is disposed at the right, left, and bottom sides of the transparent cover plate 14, respectively. Each light bar device 16 includes at least one light emitting unit 22 and a light guide bar 24. The light emitting unit 22 is used for emitting light. The light emitting unit 22 can be an infrared light emitting diode for emitting invisible light, but is not limited thereto. The light guide bar 24 is disposed at a light emitting side of the light emitting unit 22 for guiding the light emitted by the light emitting unit 22 into the transparent cover plate 14. As for the related light guide design, it is commonly seen in the prior art, such as attaching a reflection sheet onto the light guide bar 24, and its related description is therefore omitted herein for simplicity. In such a manner, via the light guide design of the light guide bar 24, the light bar device 16 can transform the spot light source of the light emitting unit 22 into a linear light source for making the light emitted by the light emitting unit 22 uniformly incident into the transparent cover plate 14. It should be noted that the light in the transparent cover plate 14 travels in a total internal reflection manner.

The optical sensing device 18 is disposed at a corner side of the transparent cover plate 14, meaning that the optical sensing device 18 and the transparent cover plate 14 are substantially located at the same horizontal surface. As shown in FIG. 1, in this embodiment, the optical sensing device 18 is disposed at the left and right corner sides of the transparent cover plate 14, respectively. The optical sensing device 18 can be a CMOS (Complementary Metal-Oxide Semiconductor) sensor. The optical sensing device 18 is used for sensing a reduced optical signal caused by total internal reflection of the light in the transparent cover plate 14 being frustrated at a position where a touch object (e.g. a user's finger or a stylus) touches the touch surface 20, and is further used for positioning the touch object according to the reduced optical signal.

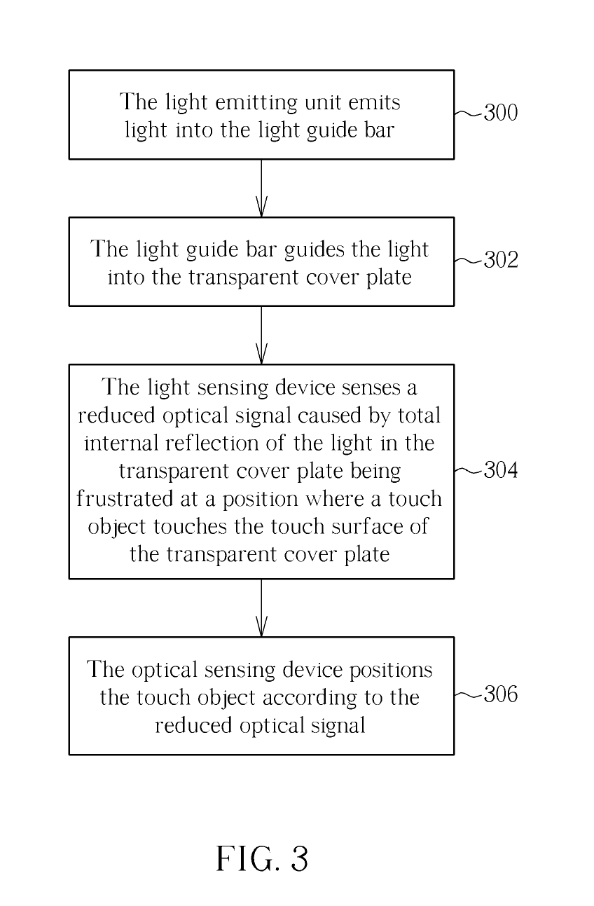

More detailed description for optical touch positioning of the optical touch module 10 is provided as follows. Please refer to FIG. 3, which is a flowchart of a method for utilizing the optical touch module 10 in FIG. 1 to position a touch object. The method includes the following steps.

Step 300: The light emitting unit 22 emits light into the light guide bar 24;

Step 302: The light guide bar 24 guides the light into the transparent cover plate 14;

Step 304: The light sensing device 18 senses a reduced optical signal caused by total internal reflection of the light in the transparent cover plate 14 being frustrated at a position where a touch object touches the touch surface 20 of the transparent cover plate 14;

Step 306: The optical sensing device 18 positions the touch object according to the reduced optical signal.

In the following, the said steps is described in view of positioning of the optical sensing device 18 located at the right corner side of the transparent cover plate 14 in FIG. 1. As for positioning of the optical sensing device 18 located at the left corner side of the transparent cover plate 14, it can be reasoned by analogy and therefore omitted herein.

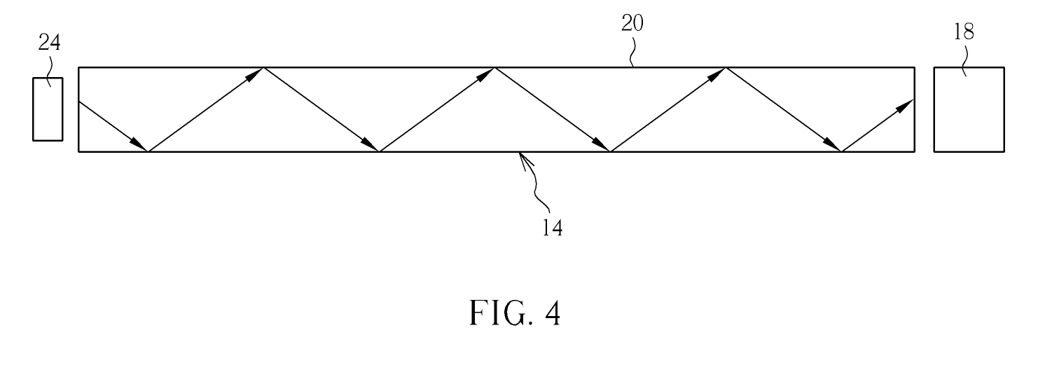

The optical touch module 10 can utilize the light guide bar 24 to achieve the purpose that the light emitted by the light emitting unit 22 can be uniformly incident into the transparent cover plate 14. That is, the light emitting unit 22 emits the light to the light guide bar 24 (Step 300), and then the light guide bar 24 diffuses the light in Step 302 so that the light can be uniformly incident into the transparent cover plate 14. And the light in the transparent cover plate 14 travels in a total internal reflection manner. In such a manner, the optical sensing device 18 can establish an optical sensing mechanism on the transparent cover plate 14 by sensing whether the total internal reflection of the light is frustrated or not. The total internal reflection of the light in the transparent cover plate 14 is as shown in FIG. 4.

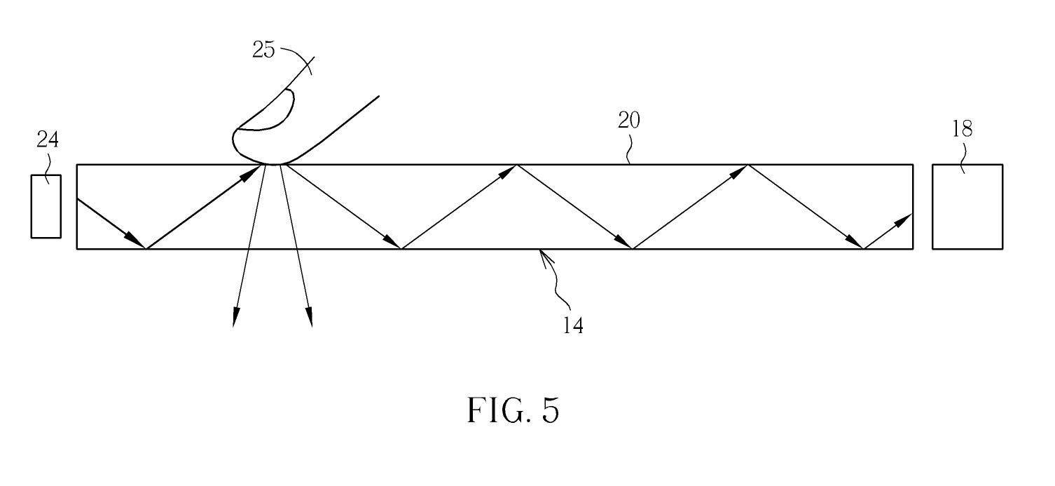

Please refer to FIG. 4 and FIG. 5. FIG. 5 is a side view of the touch surface 20 of the transparent cover plate 14 in FIG. 4 being touched by a touch object 25. As shown in FIG. 5, a user utilizes the touch object 25 (e.g. the user's finger in FIG. 5 or a stylus) to touch a position as shown in FIG. 5 for performing touch operations. At the same time, since scattering of the light occurs at the position due to the touch object 25 (as shown in FIG. 5), meaning that the total internal reflection of the light as shown in FIG. 4 is frustrated by the touch object 25, a part of the light is emitted out of the transparent cover plate 14. As a result, the optical sensing device 18 senses a reduced optical signal caused by the total internal reflection of the light in the transparent cover plate 14 being frustrated at the position (Step 304). Finally, as known in Step 306, according to the reduced optical signal, the relative angle between the touch object 25 and the optical sensing device 18 at the right corner side of the transparent cover plate 14 can be determined. Similarly, the relative angle between the touch object 25 and the optical sensing device 18 at the left corner side of the transparent cover plate 14 can also be determined according to the said steps. Thus, the plane coordinates of the touch object 25 on the touch surface 20 can be calculated accordingly based on trigonometric functions, so as to complete plane positioning of the touch object 25. As for related description for the trigonometric functions utilized in plane positioning of the touch object 25, it is commonly used in the prior art and therefore is omitted herein.

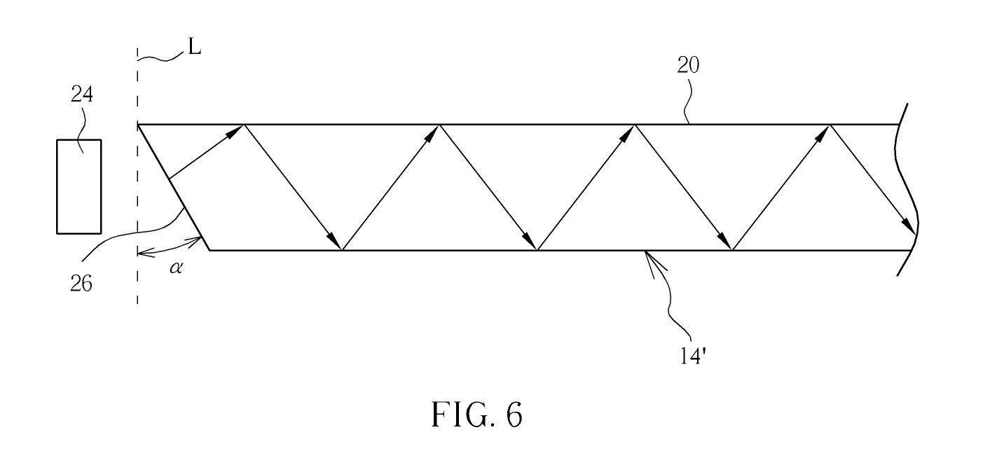

To be noted, for reducing the probability that the total internal reflection of the light is not frustrated by the touch object 25 when the touch width (usually about 10 mm) of the touch object 25 on the touch surface 20 is smaller than the distance between two adjacent reflections of the light in the transparent cover plate 14 relative to the touch surface 20, a structure for increasing times of reflection of the light in the transparent cover plate 14 can be formed at a position of the transparent cover plate 14 corresponding to the light guide bar 24. For example, please refer to FIG. 6, which is a partial side view of the transparent cover plate 14′ and the light guide bar 24 according to another embodiment of the present invention. Components both mentioned in this embodiment and the said embodiment represent components with similar functions or structures. The major difference between the transparent cover plate 14′ and the transparent cover plate 14 is the structural design on the light entrance surface of the transparent cover plate. As shown in FIG. 6, a slant-cut structure 26 is formed at a position of the transparent cover plate 14′ corresponding to the light guide bar 24. A specific angle α is included between the slant-cut structure 26 and a normal L of the transparent cover plate 14′, which can be between 30° to 60°. In such a manner, compared FIG. 6 with FIG. 4, times of reflection of the light in the transparent cover plate 14′ in FIG. 6 is increased correspondingly. In other words, via the design of forming the slant-cut structure 26 on the transparent cover plate 14′, the distance between two adjacent reflections of the light in the transparent cover plate 14′ relative to the touch surface 20 can be decreased accordingly. Thus, the transparent cover plate 14′ can efficiently reduce the probability that the total internal reflection of the light is not frustrated by the touch object 25, so as to enhance sensitivity of the optical touch module 10 in optical touch positioning.

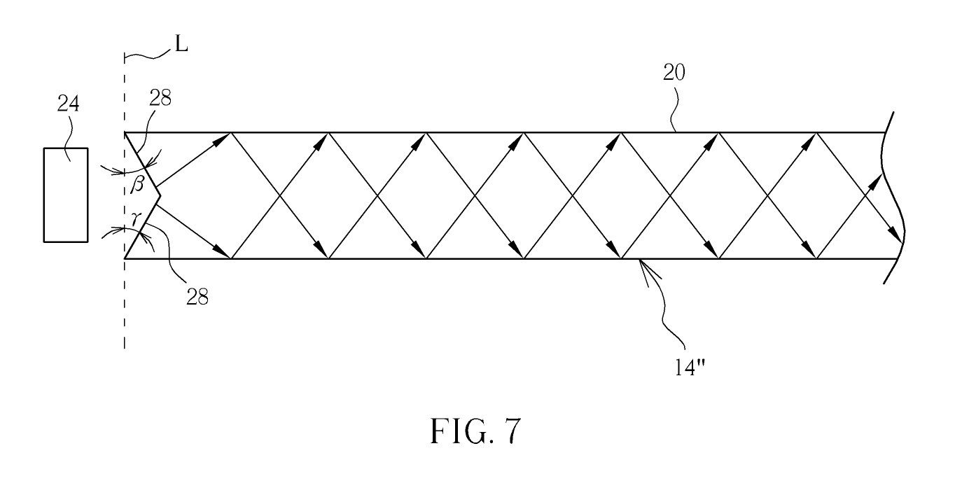

Furthermore, please refer to FIG. 7, which is a partial side view of the transparent cover plate 14″ and the light guide bar 24 according to another embodiment of the present invention. Components both mentioned in this embodiment and the said embodiment represent components with similar functions or structures. The major difference between the transparent cover plate 14″ and the transparent cover plate 14′ is the structural design on the light entrance surface of the transparent cover plate. As shown in FIG. 7, two slant-cut structures 28 are formed at a position of the transparent cover plate 14″ corresponding to the light guide bar 24. The two slant-cut structures 28 intersect inwardly with each other relative to the transparent cover plate 14″. Specific angles β and γ are respectively included between the two slant-cut structures 28 and the normal L of the transparent cover plate 14″, which can be between 30° to 60°. In such a manner, compared FIG. 7 with FIG. 6, times of reflection of the light in the transparent cover plate 14″ in FIG. 7 is increased. In other words, via the design of forming two slant-cut structures 28 on the transparent cover plate 14″, the distance between two adjacent reflections of the light in the transparent cover plate 14″ relative to the touch surface 20 can be further decreased. Thus, the transparent cover plate 14″ can reduce the probability that total internal reflection of the light is not frustrated by the touch object 25 more efficiently, so as to further enhance sensitivity of the optical touch module 10 in optical touch positioning.

The structural design on the transparent cover plate is not limited to the said embodiment. That is, designs of forming the structure for increasing times of reflection of light at a position of the transparent cover plate corresponding to the light guide bar may fall within the scope of the present invention. For example, a continuous tooth structure can be formed on a position of the transparent cover plate corresponding to the light guide bar, the vertex angle of which is substantially between 60° to 120°.

Compared with the prior art, the present invention utilizes assembly of the transparent cover plate, the light bar device and the optical sensing device to make the optical sensing device capable of sensing reduced optical signals caused by the total internal reflection of the light in the transparent cover plate being frustrated at a position where a touch object touches the touch surface. Accordingly, the present invention can establish an optical sensing mechanism on the touch surface of the transparent cover plate, so as to achieve the purpose of performing plane positioning of the touch object on the touch surface. In such a manner, since there is no need to additionally heighten an outer frame of a plane (e.g. a display panel) where the optical touch module is disposed for containing the optical sensing device and the light emitting unit and light in the transparent cover plate travels in a total internal reflection manner, the present invention can not only solve the said problem that the appearance of the display panel is influenced and dust accumulates on the light reflection bars and the optical sensing devices easily, but also make the optical sensing device capable of sensing the light precisely even if the transparent cover plate deforms after being used over a period of time, so as to avoid the said problem that the position of the light reflection bar relative to the optical sensing device needs to be calibrated frequently.

Furthermore, the optical touch module of the present invention can utilize the light guide bar to transform the light emitting unit from a spot light source into a linear light source, so as to make light emitted by the light emitting unit incident into the transparent cover plate uniformly. As a result, the present invention can efficiently avoid the said condition that signal attenuation of the light is too small when the light is incident into the light reflection bar at a large angle, so as to further enhance positioning accuracy of the optical sensing device.

Those skilled in the art will readily observe that numerous modifications and alterations of the device and method may be made while retaining the teachings of the invention.

What is claimed is:

1. An optical touch module comprising:
a transparent cover plate disposed on a display panel and having a touch surface;
at least one light bar device disposed along a side of the transparent cover plate, the light bar device comprising:
at least one light emitting unit for emitting light; and
a light guide bar disposed at a light emitting side of the light emitting unit for guiding light emitted by the light emitting unit into the transparent cover plate; and
at least one optical sensing device disposed at a corner side of the transparent cover plate for sensing a reduced optical signal caused by total internal reflection of the light in the transparent cover plate being frustrated at a position where a touch object touches the touch surface and for positioning the touch object based on the reduced optical signal.

2. The optical touch module of claim 1, wherein a slant-cut structure is formed at a position of the transparent cover plate corresponding to the light guide bar, and a specific angle is included between the slant-cut structure and a normal of the transparent cover plate.

3. The optical touch module of claim 2, wherein the specific angle is between 30° to 60°.

4. The optical touch module of claim 1, wherein two slant-cut structures are formed at a position of the transparent cover plate corresponding to the light guide bar, the two slant-cut structures intersect inwardly with each other relative to the transparent cover plate, and a specific angle is included between the two slant-cut structures and a normal of the transparent cover plate respectively.

5. The optical touch module of claim 4, wherein the specific angle is between 30° to 60°.

6. The optical touch module of claim 1, wherein a continuous tooth structure is formed at a position of the transparent cover plate corresponding to the light guide bar.

7. The optical touch module of claim 6, wherein a vertex angle of the continuous tooth structure is substantially between 60° to 120°.

8. The optical touch module of claim 1, wherein the refractive index of the transparent cover plate is between 1.5 and 1.6.

9. The optical touch module of claim 8, wherein the transparent cover plate is made of glass or resin material.

10. The optical touch module of claim 1, wherein the light emitted by the light emitting unit is invisible light.

11. The optical touch module of claim 10, wherein the light emitting unit is an infrared light emitting diode.

12. The optical touch module of claim 1, wherein the optical sensing device is a CMOS (Complementary Metal-Oxide Semiconductor) sensor.

13. A method for positioning a touch object on a plane, the method comprising:
disposing a transparent cover plate on the plane;
disposing at least one light emitting unit along at least one side of the transparent cover plate and a light guide bar located at a light emitting side of the light emitting unit;
disposing an optical sensing device on at least one corner side of the transparent cover plate;
the light guide bar guiding light emitted by the light emitting unit into the transparent cover plate;
the optical sensing device sensing a reduced optical signal caused by total internal reflection of the light in the transparent cover plate being frustrated at a position where a touch object touches the touch surface; and
the optical sensing device positioning the touch object based on the reduced optical signal.

14. The method of claim 13 further comprising:
forming a slant-cut structure at a position of the transparent cover plate corresponding to the light guide bar, a specific angle being included between the slant-cut structure and a normal of the transparent cover plate.

15. The method of claim 13 further comprising:
forming two slant-cut structures at a position of the transparent cover plate corresponding to the light guide bar, the two slant-cut structures intersecting inwardly with each other relative to the transparent cover plate, a specific angle being included between the two slant-cut structures and a normal of the transparent cover plate respectively.

16. The method of claim 13 further comprising:
forming a continuous tooth structure at a position of the transparent cover plate corresponding to the light guide bar.
